(19) United States
(12) Patent Application Publication
(10) Pub. No.: US 2009/0137093 A1
(43) Pub. Date: May 28, 2009

(54) METHOD OF FORMING FINFET DEVICE

(75) Inventor: Shian-Jyh LIN, Yonghe City (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 12/101,007

(22) Filed: Apr. 10, 2008

(30) Foreign Application Priority Data
Nov. 26, 2007 (TW) 96144734

(51) Int. Cl. H01L 21/302

(52) U.S. Cl. 438/421; 257/E21.214

(57) ABSTRACT

A method of forming a FINFET device includes providing a substrate with a plurality of trench devices arranged in array therein, each of the trench devices comprising a plug protruding above the substrate; forming a plurality of isolation structures along a first direction in the substrate adjacent to the trench devices so as to define an active area exposing the substrate; forming a spacer on each of the plug to define a reactive area between the active area and the spacer; and removing the isolation structures on the reactive area to form a fin structure in the active area.

### CROSS REFERENCE TO RELATED APPLICATIONS

This application claims the right of priority based on Taiwan Patent Application No. 096144734 entitled “METHOD OF FORMING FINFET DEVICE”, filed on Nov. 26, 2007, which is incorporated herein by reference and assigned to the assignee herein.

### FIELD OF THE INVENTION

The present invention relates to a method of forming a semiconductor device, and more particularly, relates to a method of forming a fin-type field effect transistor (FINFET) device.

### BACKGROUND OF THE INVENTION

As the integration density of semiconductor devices increases and the size of field effect transistor (FET) continuously scales down, the short channel effect becomes a severe issue due to the decrease of channel length. A multi-gate transistor is one of the means to effectively inhibit the short channel effect, and FINFET device is one of these options. FINFET device provides a three-dimensional channel, which has the advantages of reducing the leakage current from the substrate, obtaining a higher driving current, and inhibiting the short channel effect.

In order to further effectively utilize the substrate area, integrating the three-dimensional gate FINFET device with a trench device, such as a trench capacitor, becomes an advancing technique. However, the integration of the FINFET device with the trench capacitor complicates the manufacture processes and significantly reduces the process window. That is, the alignment of layers is a critical factor that affects the performance of the semiconductor device. Particularly, when the fin structure of the FINFET device is defined by lithography processes, a slight misalignment may cause the device to fail.

Therefore, there is a desire to provide a method for effectively integrating the FINFET device with the trench device without raising any alignment concerns.

### SUMMARY OF THE INVENTION

In view of the prior art drawbacks, one aspect of the present invention is to provide a method for forming a FINFET device, which incorporates the self-alignment technique to prevent the misalignment, occurred in the prior art lithography process and also maintains suitable spaces for source/drain contacts.

Another aspect of the present invention is to provide a method for forming a FINFET device, which integrates the trench device with column-like masking technique to self-alignedly define the fin structure to form a FINFET memory device.

In one embodiment of the present invention, a method of forming a FINFET device includes providing a substrate with a plurality of trench devices arranged in array therein, each of the trench devices including a plug protruding above the substrate; forming a plurality of isolation structures along a first direction in the substrate adjacent to the trench devices so as to define an active area exposing the substrate; forming a spacer on each of the plug to define a reactive area between the active area and the spacer; and removing the isolation structures on the reactive area to form a fin structure in the active area.

In an exemplary embodiment, the step of forming the plug includes forming a plurality of openings arranged in array in the substrate, each of the openings corresponding to one of the trench devices; forming an oxide layer over the substrate to fill the openings; removing a portion of the oxide layer on the substrate to remain another portion of the oxide layer in the openings; and forming a polysilicon layer on the oxide layer. Prior to the step of forming the isolation structures, the method further includes conformally forming a dielectric liner on the substrate. The step of forming the isolation structures includes defining a plurality of strip openings on two opposite sides of the trench device by a lithography technique; etching portions of the dielectric liner, the plugs, the trench devices, and the substrate to form a plurality of strip openings; and filling an oxide layer in the strip openings to form the isolation structures.

Prior to the step of filling the oxide layer in the strip openings, the method further includes thermal oxidizing the substrate. The step of forming the fin structure includes rounding the active area to form the fin structure at the time of removing the reactive area. Alternatively, additional processes are employed to modify the profile of the fin structure.

The method further includes forming a gate dielectric layer on the fin structure, forming a gate conductor on the gate dielectric layer, sequentially forming a second conductor, a metal layer, and a cap layer on the gate conductor, and partially etching the second conductor, the metal layer, and the cap layer along a second direction perpendicular to the first direction to form a control gate. The method further includes forming a dielectric spacer on the control gate.

### BRIEF DESCRIPTION OF THE DRAWINGS

FIG. 1 to FIG. 8 illustrates schematic views of various stages of forming a FINFET device in accordance with one embodiment of the present invention;

FIGS. 1A-8A and FIGS. 1B-8B are schematic cross-sectional views along the line A-A and the line B-B of FIGS. 1-8, respectively; and

FIGS. 1C-8C are schematic cross-sectional views of peripheral areas outside FIGS. 1-8.

### DETAILED DESCRIPTION OF THE INVENTION

The present invention discloses a method of forming a FINFET device, which integrates a trench device and uses the self-alignment technique to define a fin structure and maintain suitable spaces for source/drain regions. The present invention may best be understood by reference to the following description in conjunction with the accompanying drawings, in which similar reference numbers represent similar elements. Any devices, components, materials, and steps described in the embodiments are only for illustration and not intended to limit the scope of the present invention.

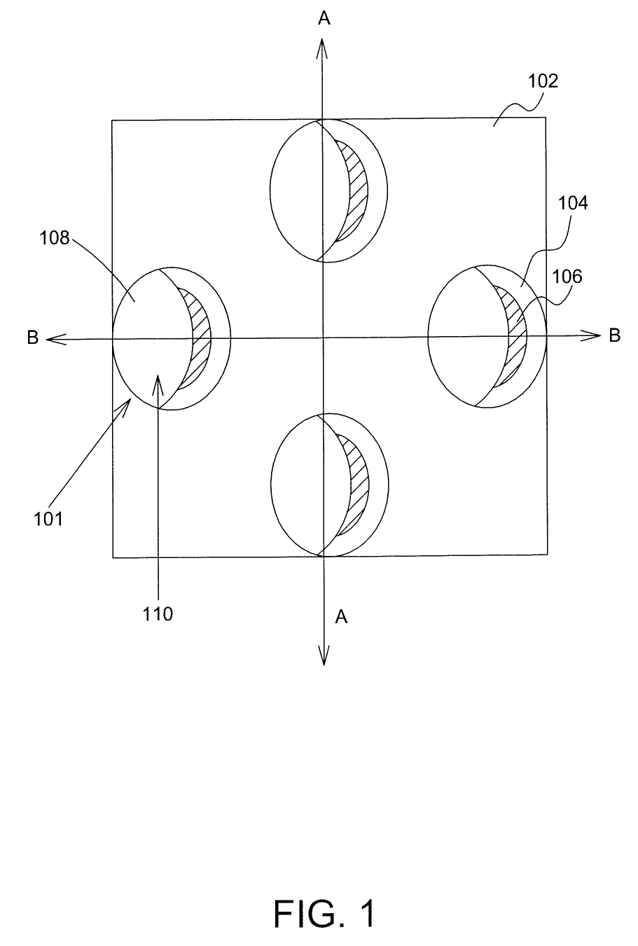

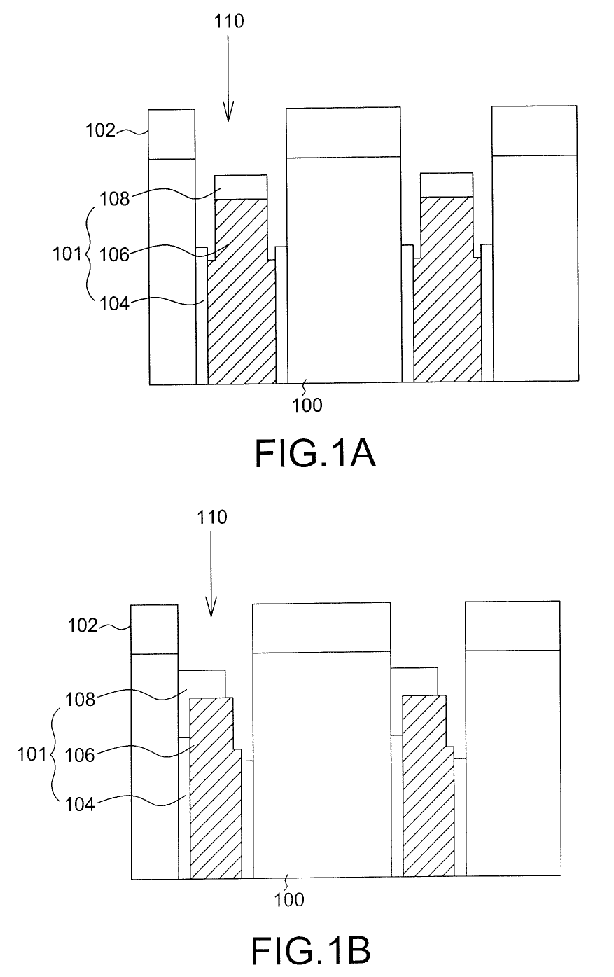

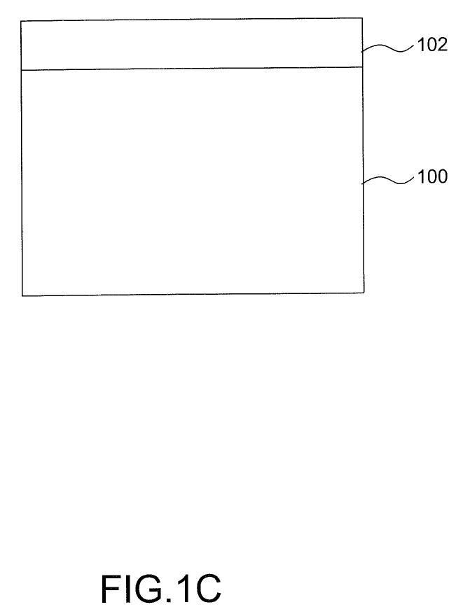

FIG. 1 to FIG. 8C illustrates schematic views of various stages of forming a FINFET device in accordance with one embodiment of the present invention. FIGS. 1-8 are respective top views at various stages. FIGS. 1A-8A and FIGS. 1B-8B are schematic cross-sectional views along the line A-A and the line B-B of FIGS. 1-8, respectively, and FIGS. 1C-8C are schematic cross-sectional views of peripheral areas outside FIGS. 1-8.

In one embodiment, the present invention provides a method of forming a FINFET device, which is exemplarily illustrated by way of a memory device with a trench capacitor and a fin type transistor. It is noted that the present invention is applicable to any semiconductor device in need of a fin structure. With reference to FIGS. 1A, 1B, and 1C, a substrate 100 is provided with a trench device formed therein. In one exemplary embodiment, the trench device formed in the substrate 100 includes a single-sided buried strap trench capacitor. For example, the substrate 100 may be any suitable semiconductor substrate, which includes but not limited to a silicon substrate, a semiconductor-on-insulator (SOI) substrate, or a compound semiconductor substrate. In this embodiment, the substrate 100 is a silicon substrate. The single-sided buried strap trench capacitor can be a conventional capacitor known in the art, and formed by any suitable processes. For example, a hardmask 102 is first formed on the substrate 100, and then a trench is formed in the substrate 100. A lower electrode, a capacitor dielectric, an upper electrode, a collar dielectric, a conductor, and a single-sided buried strap are sequentially formed in the trench. In order not to obscure the present invention, only the upper portion of the trench capacitor is illustrated, however, the person skilled in the art should understand that there will be other elements. Therefore, as shown in FIG. 1, four single-sided buried strap trench capacitors are arranged in array as known in the art. The word “array”, as used in this specification defines a staggered arrangement, not only from the cross section of view, but also from the top view of the structure. As shown in FIGS. 1A and 1B, which are respective cross-sectional views along the lines A-A and B-B of FIG. 1, the substrate structure includes the substrate 100 and the hardmask 102 on the substrate 100. The hardmask 102 may include an oxide layer, a nitride layer or a combination thereof. The hardmask 102 has a plurality of openings 110 arranged in array, and each of the openings 110 exposes a trench device 101 formed in the substrate 100. That is, the trench device 101 shown in the figure includes a collar dielectric 104, a conductor 106, and a single-sided buried strap 108 within the substrate 100. As shown in FIG. 1B, the single-sided buried strap 108 does not fully fill the trench so that an opening 110 is formed. Moreover, the present invention may integrate the FINFET device in the array area with the peripheral circuit in the peripheral area. As shown in FIG. 1C, a schematic cross-sectional views of the peripheral area outside FIG. 1 is illustrated, which includes the hardmask 102 on the substrate 100.

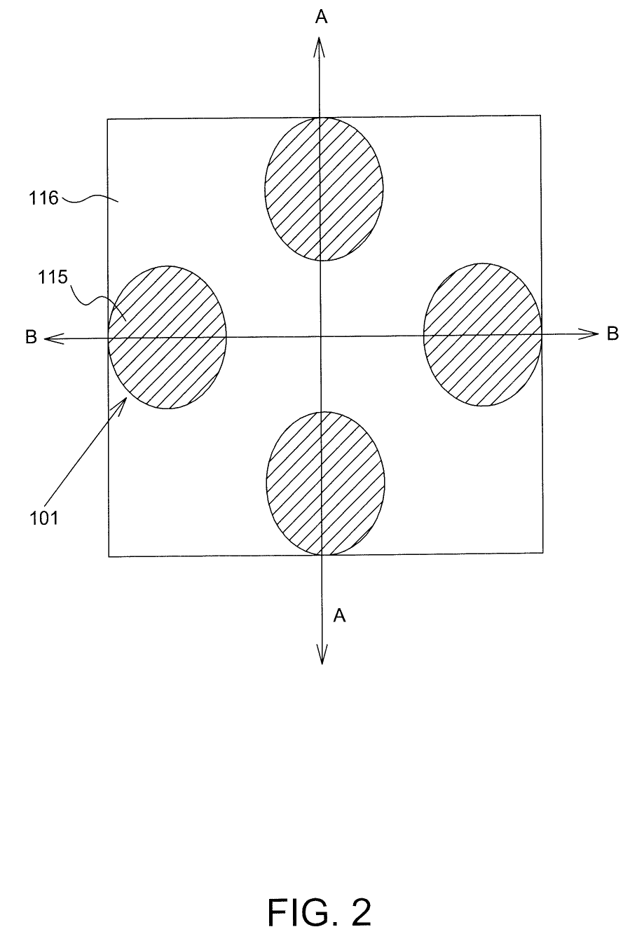

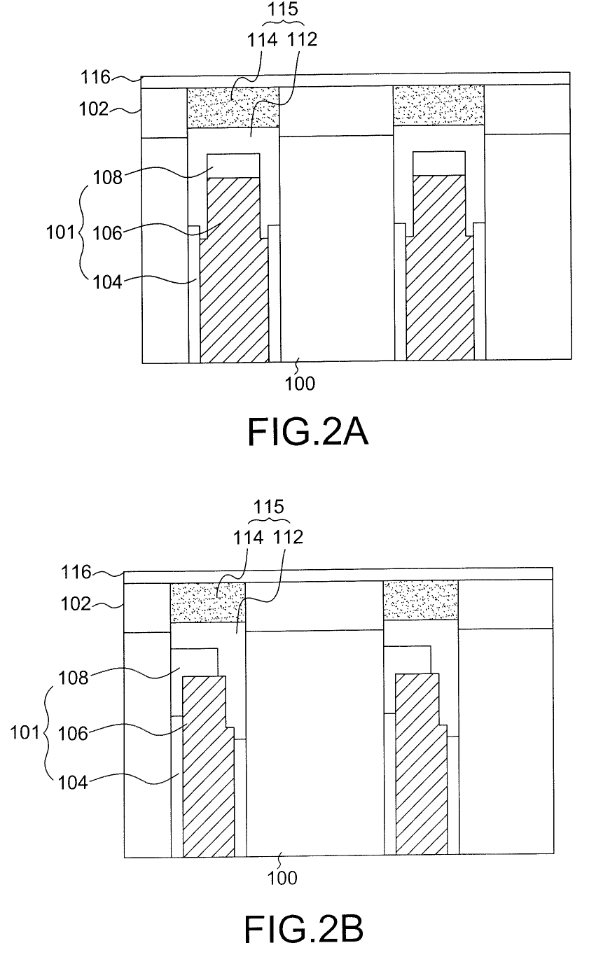

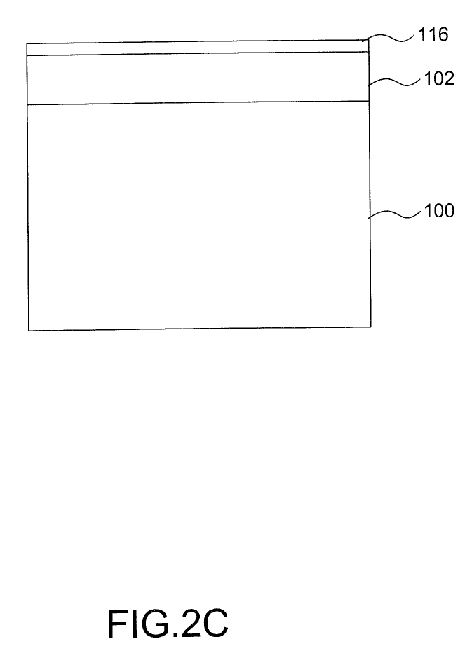

With reference to FIGS. 2 and 2A-2C, after the structure of FIG. 1 is formed, a plug including a dielectric layer 112 and a polysilicon layer 114 is formed in each of the openings 110. For example, a blanket oxide layer is deposited over the entire structure and then chemical mechanical polished or etched back to leave the opening 110 not fully filled. A polysilicon layer 114 is then blanket-deposited and chemical mechanical polished to expose the hardmask 102. The polysilicon layer 114 is substantially coplanar with the hardmask 102. Then, a dielectric liner 116 is formed over the entire structure, and accordingly the structure shown in FIG. 2 is formed. For example, the dielectric liner 116 may be a nitride layer, which is simultaneously formed on the hardmask 102 in the peripheral area, as shown in FIG. 2C.

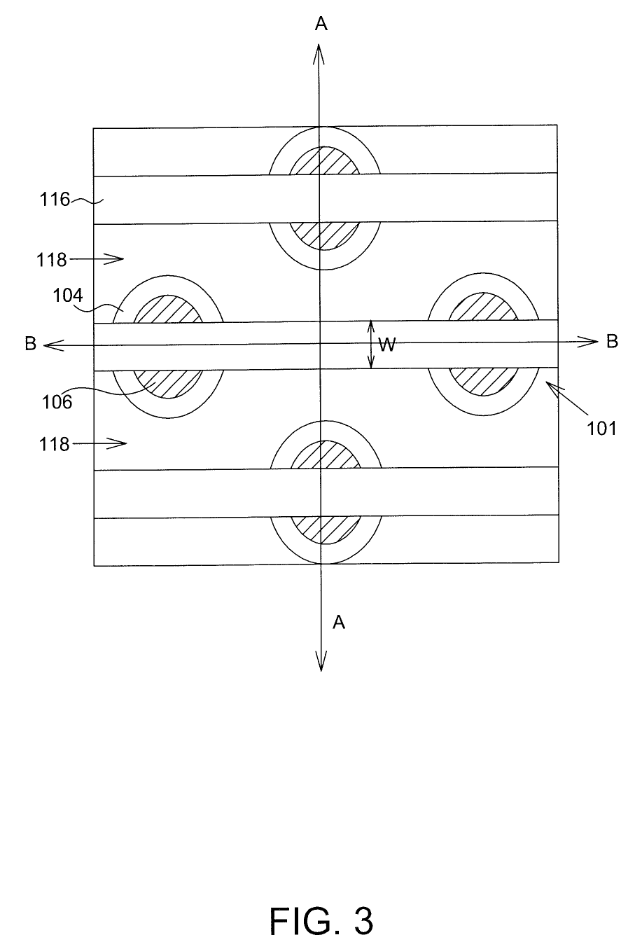

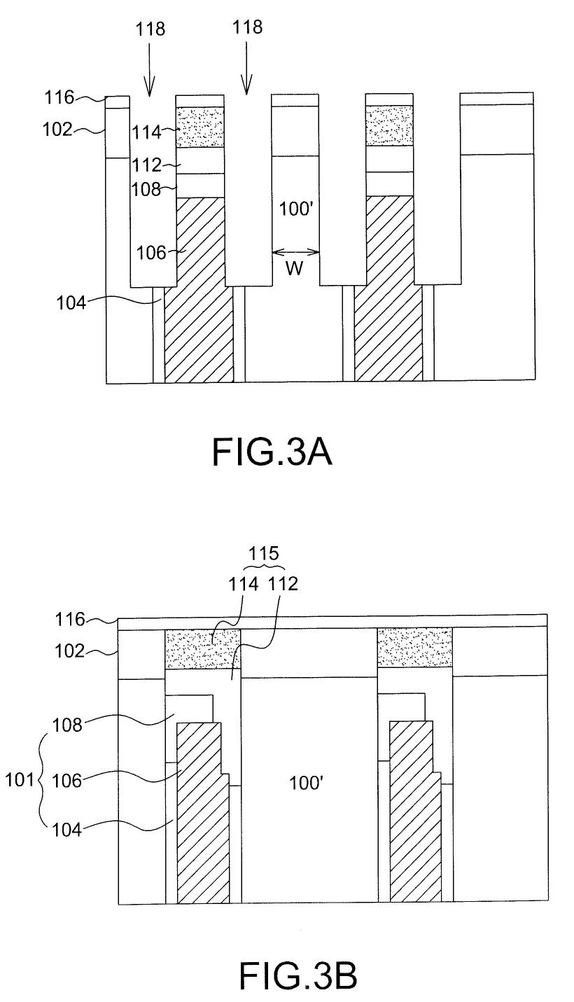

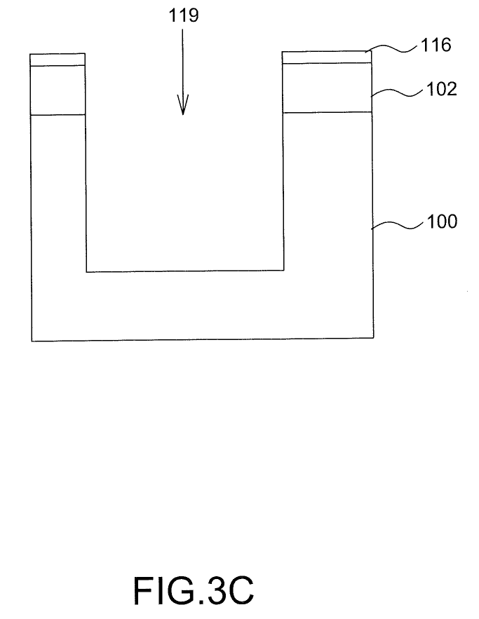

With reference to FIGS. 3 and 3A-3C, after the structure of FIG. 2 is formed, a plurality of strip openings 118 are formed in parallel along the B-B direction so as to define a portion of the substrate 100′ between two adjacent trench devices 101. For example, by using the lithography technique, a patterned photoresist (not shown) is formed on the dielectric liner 116 to define a pattern of parallel strip openings. The underlying unprotected layers, such as portions of dielectric liner 116, the hardmask 102, the polysilicon layer 114, the dielectric layer 112, the singled-sided buried strap 108, the conductor 106, the collar dielectric 104, and the substrate 100, are etched by using the patterned photoresist as a mask. After the patterned photoresist is removed, a structure with the strip openings 118 shown in FIG. 3 is formed. As shown in FIG. 3, the strip openings 118 are formed on two opposite sides of the trench devices 101 to expose a portion of the collar dielectric 104 and a portion of the conductor 106 and in turn, to define a portion of the substrate 100′ between two adjacent trench devices 101. As such, the width of the fin structure to be formed is defined as the width of the portion of the substrate 100′ (W), and the width of the source/drain regions is maintained at a suitable range. Moreover, by controlling the etching time, the depth of the strip openings 118 can be effectively controlled. Please note that the patterned photoresist can be also formed with a pattern of trench isolations in the peripheral area, so that trench isolation openings 119 can be formed in the peripheral area during the same etching procedure, as shown in FIG. 3C.

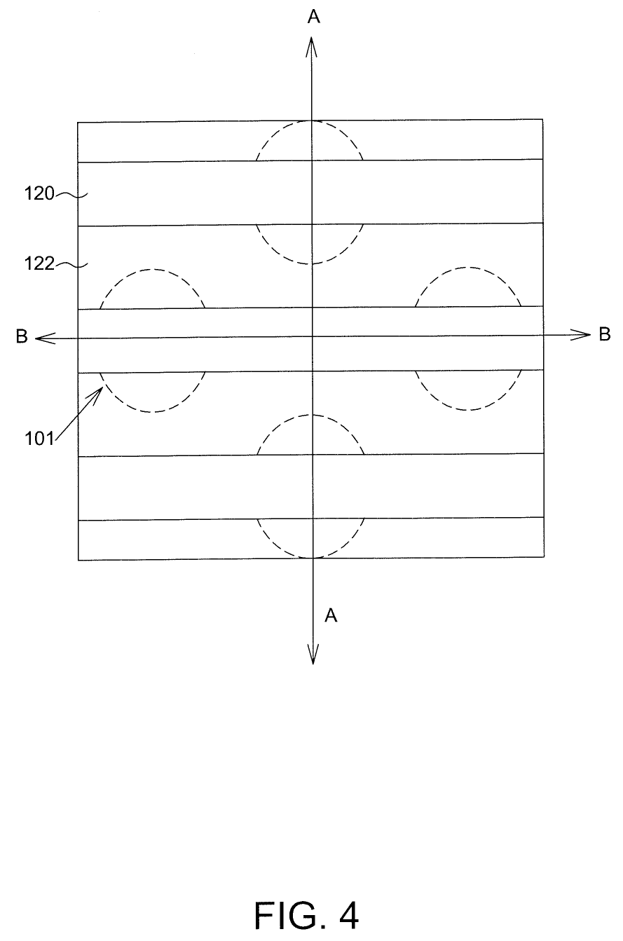

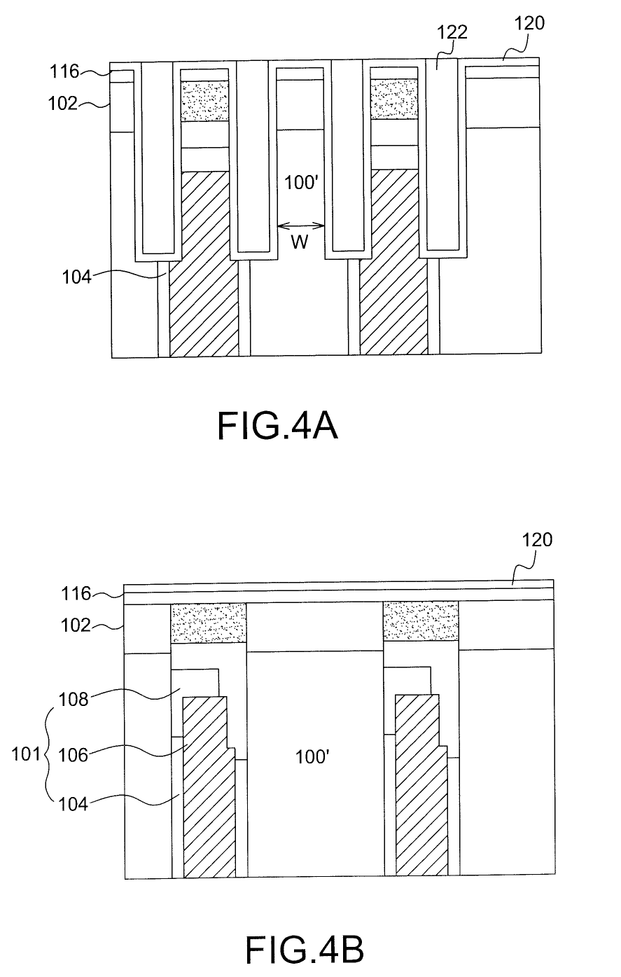

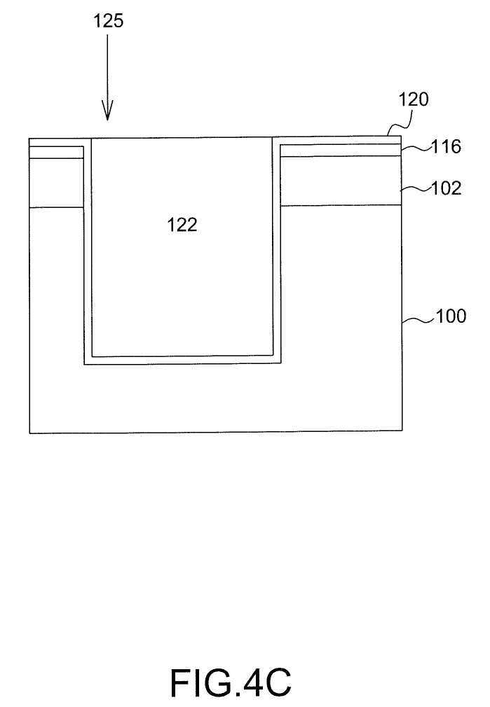

With reference to FIGS. 4 and 4A-4C, a conformal liner 120 is formed on the structure of FIG. 3, for example, on the entire structure and the sidewall and the top of the strip openings 118. A filling layer 122 is formed on the conformal liner 120 to fill the strip openings 118. At the same time, the conformal liner 120 and the filling layer 122 are also formed in the trench opening 119 in the peripheral area to formed a trench isolation, as shown in FIG. 4C. For example, a nitride layer is conformally formed on the entire structure serving as the conformal liner 120, and an oxide layer serving as the filling layer 122 is blanket deposited on the nitride layer to fill the strip openings 118 and then chemical mechanical polished to expose the conformal liner 120, so that the remaining filling layer 122 become strip-like filling layer, i.e. isolation structures. Optionally, prior to the step of forming the conformal liner 120, a thermal oxidization process may be performed on the structure of FIG. 3 to form an oxide film on the sidewall ad the bottom of the substrate 100′ within the strip openings 118, which may repair the interface damage caused by the etching of the strip openings 118. If the oxide film exists, the conformal liner 120 within the strip opening 118 is formed on the oxide film. Similarly, the oxide film may also be formed in the trench isolation opening 119 that is not deliberated again.

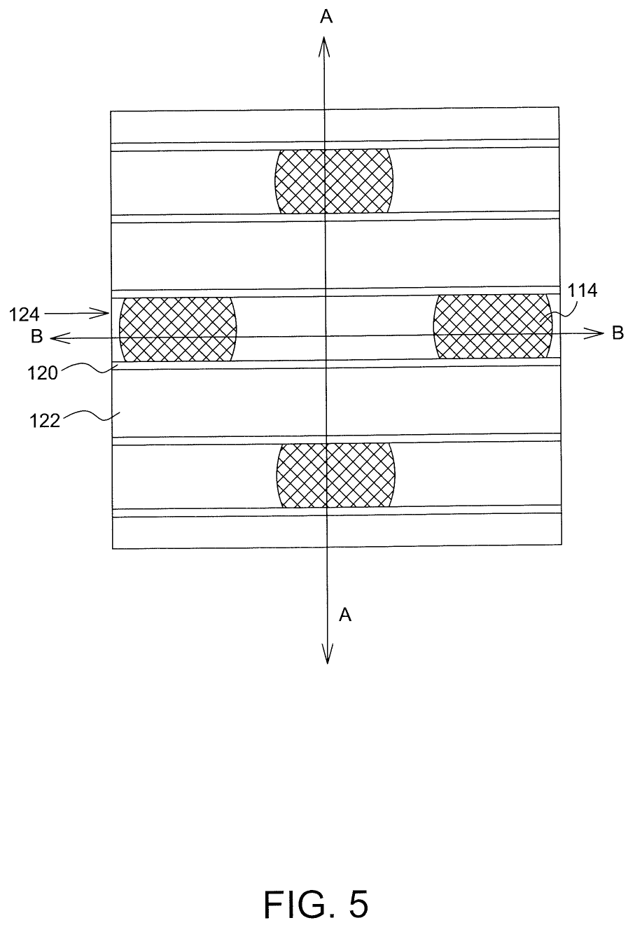

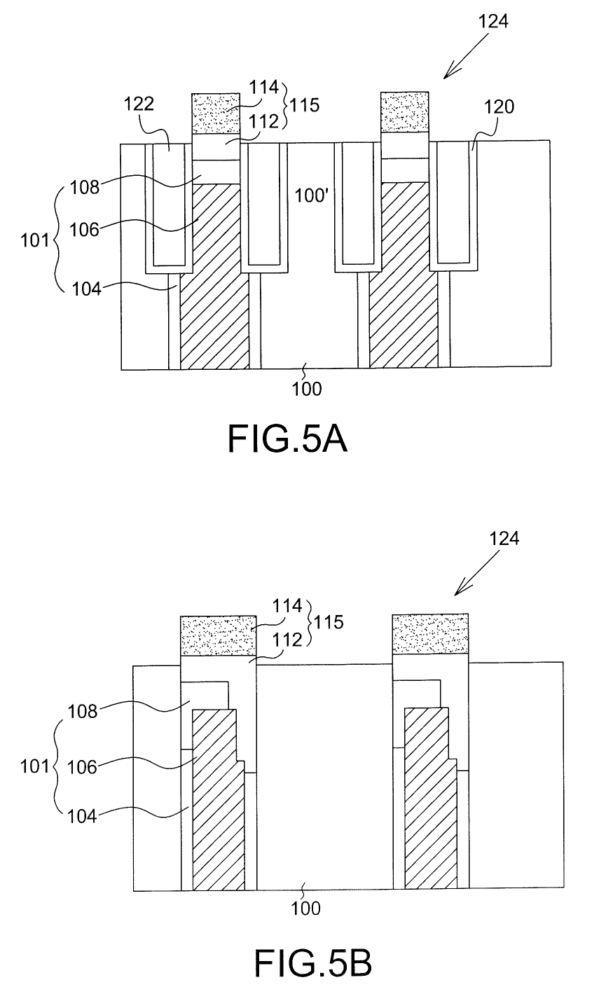

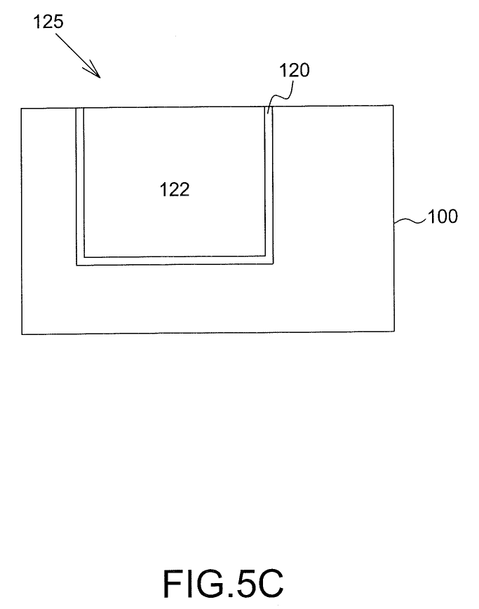

With reference to FIGS. 5 and 5A-5C, after the structure of FIG. 4 is formed, the plug 115 including the polysilicon layer 114 and the dielectric layer 112 is maintained to protrude above the substrate 100 and other layers above the substrate 100 are removed. For example, the filling layer 122 above the substrate 100 is removed by wet etching process, i.e. pulled back down to a depth about the surface of the substrate 100, so as to expose the conformal liner 120 on the sidewalls of the dielectric liner 116, the mask layer 102 and the polysilicon layer 114. Then, the dielectric liner 116, the mask layer 102, and the exposed conformal liner 120 are removed. In this embodiment, the dielectric liner 116, the mask layer 102, and the conformal liner 120 are nitride layers, so that these layers 116, 102, 120 may be removed by a same etch process. Since the polysilicon layer 114 and the oxide layer 112 has an etch selectivity with respect to the nitride layer, the etch process has no substantial impact on the polysilicon layer 114 and the layers protected thereunder. As a result, four plugs 124 protruding above the substrate 100 are formed, as shown in FIG. 5, while trench isolations 125 are formed in the peripheral area, as shown in FIG. 5C. The trench isolations 125 are formed to be preferably coplanar with the substrate 100 or slightly higher than the surface of the substrate 100. If desired, ion implantation process can be performed to implant dopants into the substrate 100 to form a well, which may have different conductivity type, such as P type or N type, in accordance with different applications. The ion implantation may be conducted on both the array area and the peripheral area.

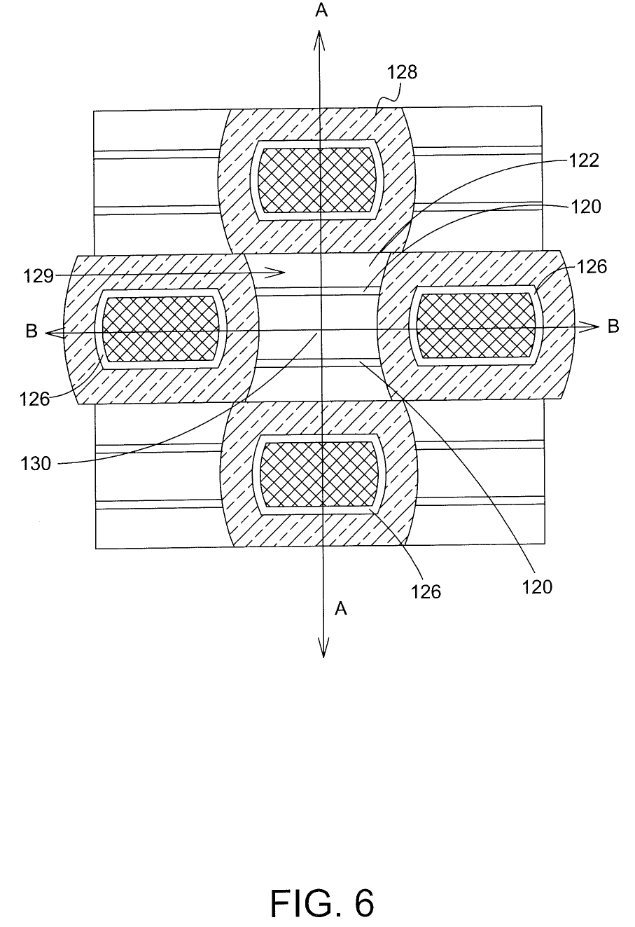

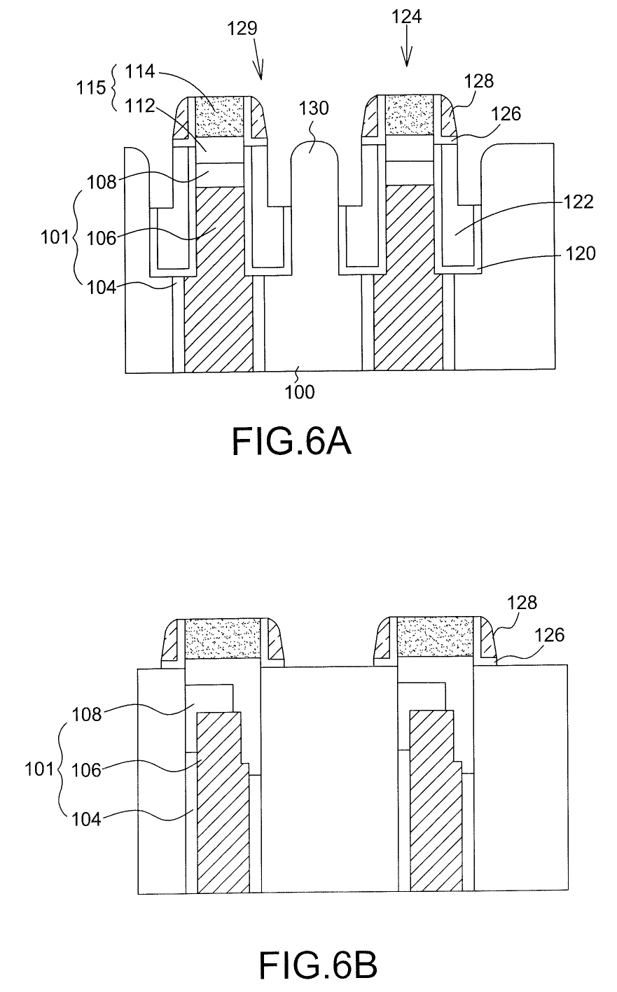

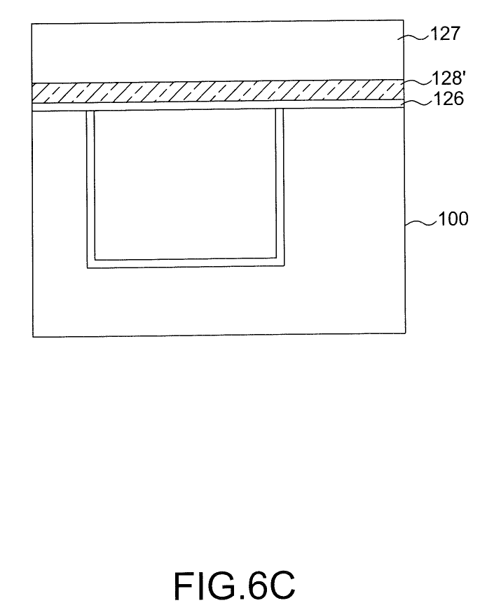

With reference to FIGS. 6 and 6A-6C, a conformal dielectric layer 126 is formed on the structure shown of FIG. 5. A spacer 128 is formed on the conformal dielectric layer 126 corresponding to the sidewall of the plug 124. By using the spacer 128 as a mask, a portion of the filling layer 122 is removed so as to form a fin structure 130, which corresponds to the portion of substrate 100′. At this point, a resist layer 127 is formed on the conformal dielectric layer 126 in the peripheral area so that the peripheral area is protected against the processes performed on the array area. For example, a conformal nitride layer may be formed on the structure of FIG. 5 to serve as the conformal dielectric layer 126. A polysilicon layer 128′ is conformally formed over the entire structure, and then, a photoresist layer 127 is formed and patterned to protect the peripheral area so that the following processes are performed on the array area only. That is, the polysilicon layer 128′ is anisotropically etched to form the spacer 128 on the conformal dielectric later 126, which is on the sidewall of the plug 124. Please note that the spacer 128 preferably has a thickness sufficient to surround the central space defined by the four plugs 124. That is, as shown in FIG. 6, the spacers 128 of the four plugs 128 extend out to self-alignedly form an opening 129, which is encompassed by the four column-like structures, i.e. the four plugs 124 with the spacers 128. The fin structure 130 is located within in the opening 129. A portion of the substrate 100′ within the opening 129 serves as an active area, which is later to be used for the fin structure, and a portion of the filling layer 122 within the opening 129 is defined as a reactive area, which is between the spacer 128 and the active area 100′. Therefore, when the spacers 128 are used as a mask to etch the unprotected conformal dielectric layer 126 and the filling layer 122, i.e. the reactive area, the fin structure 130 can be self-alignedly formed, as shown in FIG. 6A. Please note that by controlling the etching time, the etching rate, and the etching direction, the active area 100′ can be converted to form the fin structure 130, which can be rounded at the top so as to reduce the spike discharging and the electric field effect. Alternatively, additional processes, such as dipping in acid solution or ammonia water, or thermal oxidization, can be employed to modify the profile of the fin structure 130 in accordance with different design need. Moreover, the height (or the depth) of the fin structure 130 can be effectively controlled by controlling the etching time. Please note that the photoresist layer 127 can be removed at the time of removing the reactive area of the filling layer 122 or by an independent process.

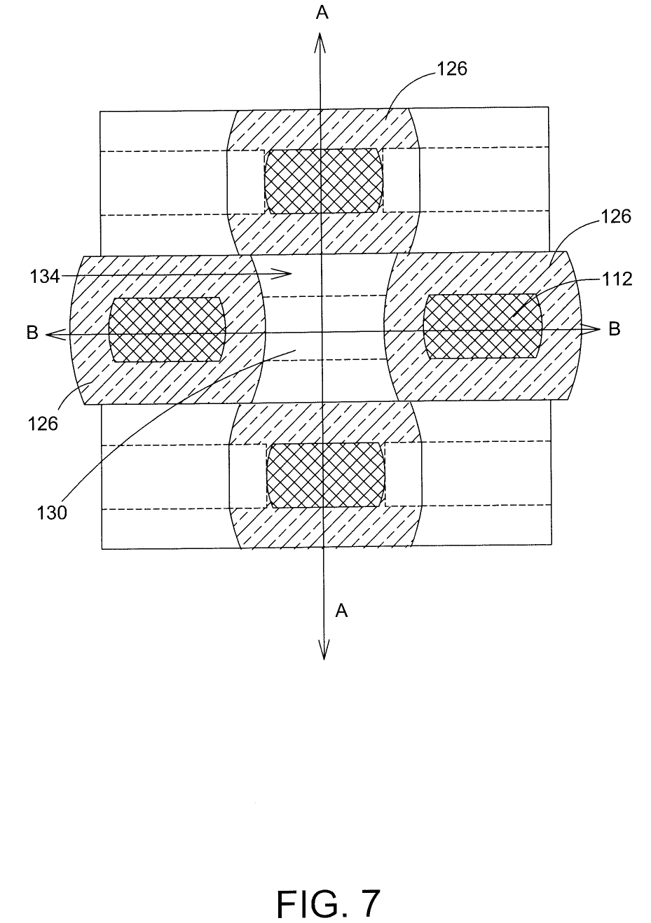

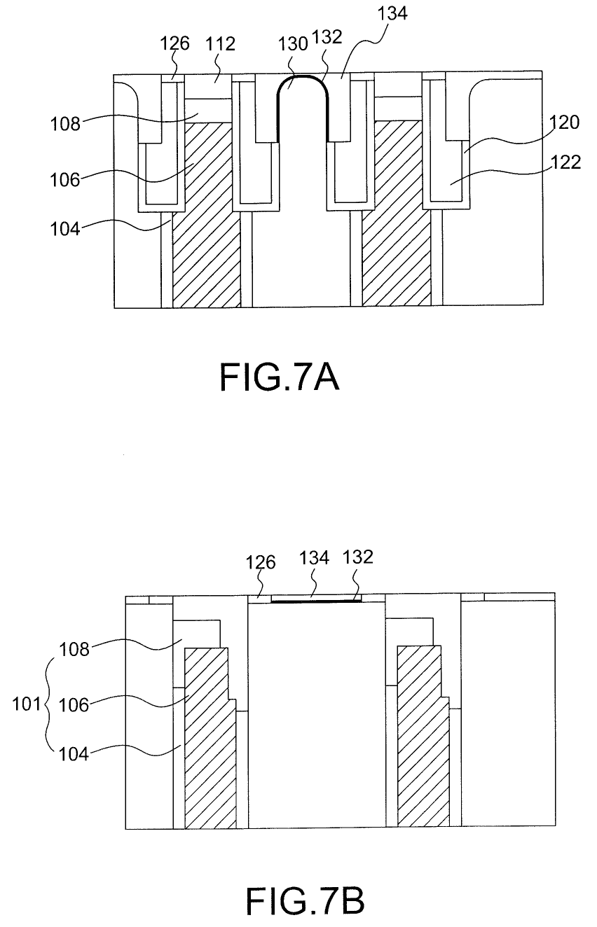

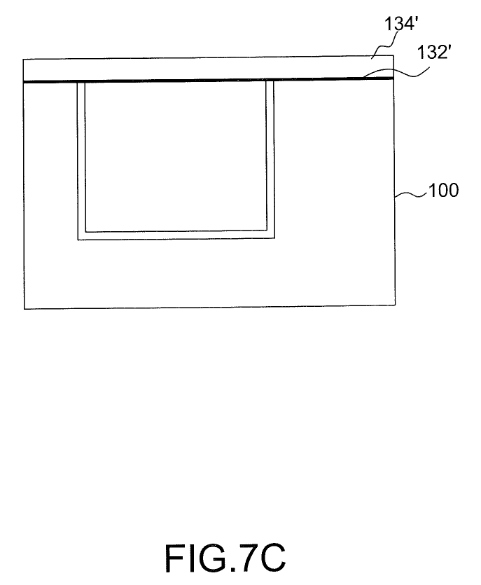

With reference to FIGS. 7 and 7A-7C, after the resist layer 127 in the peripheral area is removed, a gate dielectric layer 132 and a gate conductor 134 are to be formed. For example, the gate dielectric layer 132 can be formed by thermal oxidation or atom layer deposition (ALD) to cover the surface of the fin structure 130. The gate dielectric layer 132 may be thermal oxide, oxynitride, or high K dielectric materials. The gate conductor 134 is formed on the gate dielectric layer 132 to fill the gap between the fin structure 130 and the filling layer 122. Then, the gate conductor 134 and the plug 124 are chemical mechanical polished to expose the conformal dielectric layer 126 on the filling layer 122, as shown in FIG. 7A. In one exemplary embodiment, the gate conductor 134 may be a polysilicon layer or a metal layer. Moreover, the overlying layers above the substrate 100 in the peripheral area, such as the conformal dielectric layer 126, the gate dielectric layer 132, and the gate conductor 134, can be removed while the array area is protected by a resist layer (not shown). A gate dielectric layer 132′ and a gate conductor 134′ are subsequently formed on the substrate 100 in the peripheral area, and the resist protecting the array area is then removed, as shown in FIG. 7C.

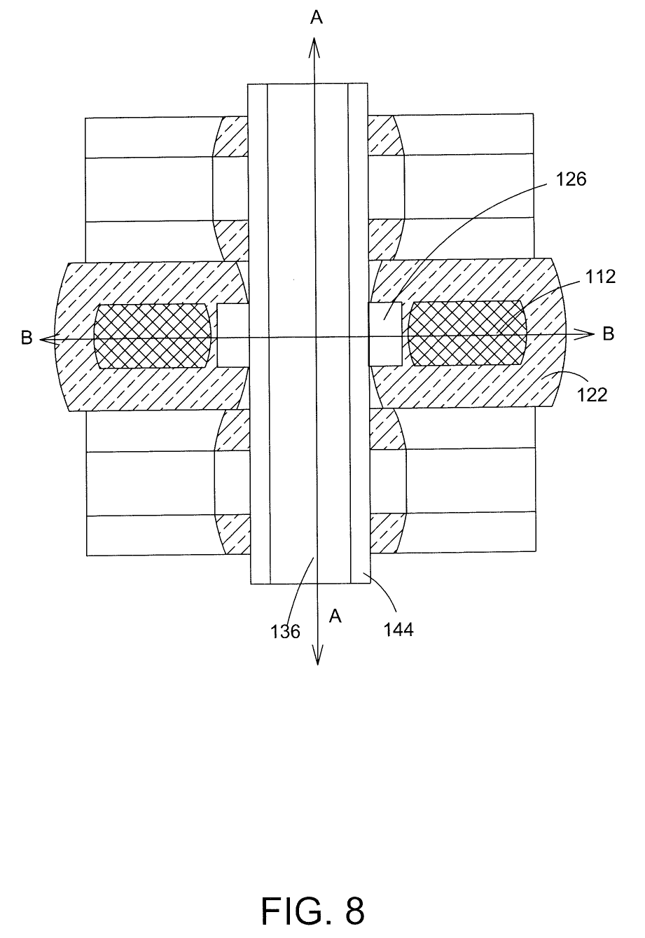

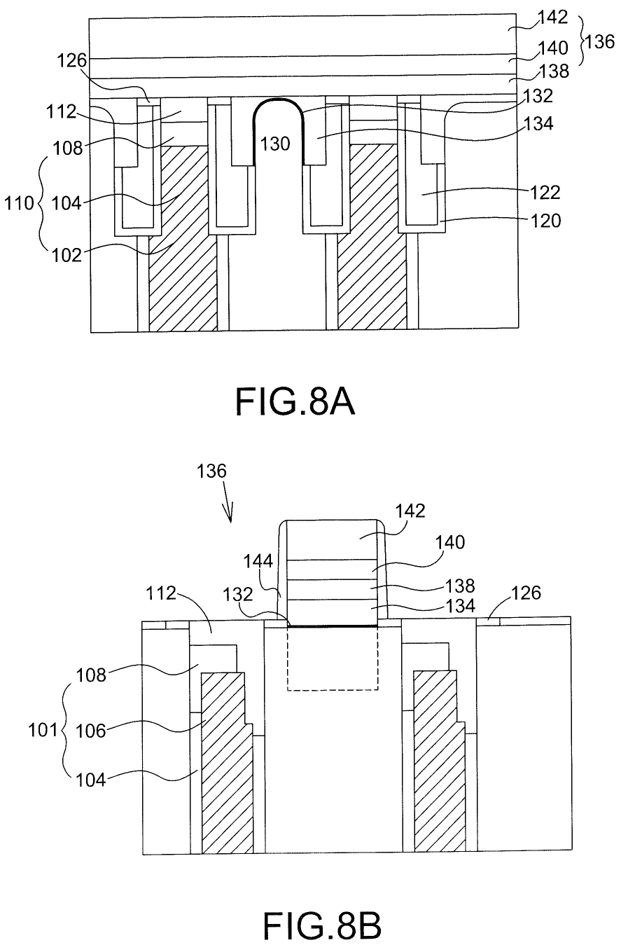

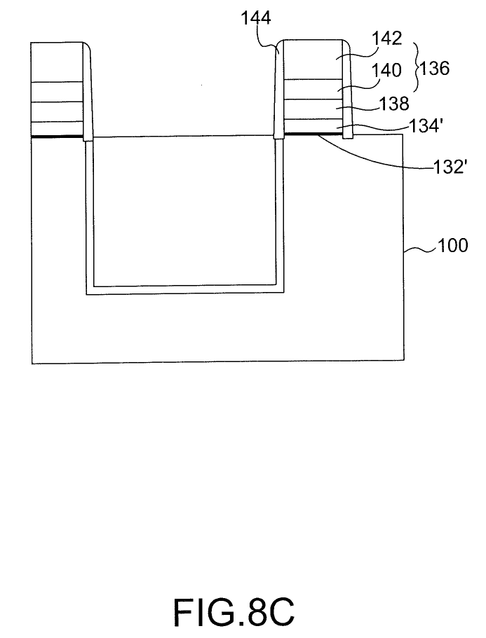

With reference to FIGS. 8 and 8A-8C, a control gate 136 is defined along A-A direction for both array area and peripheral area. For example, a second gate conductor 138, such as a polysilicon layer, is blanket-formed on the gate conductor 134, a metal layer 142 is optionally formed on the second gate conductor 138, and a cap layer 142 is formed on the metal layer 140. The metal layer 140 and the cap layer 142 can be any suitable material known in the art, such as tungsten and nitride, respectively. A patterned photoresist (not shown) is then formed on the cap layer 142 to define the pattern of control gate in the A-A direction overlying the fin structure 130 while the peripheral area can also be defined with a control gate pattern. Then, the unprotected portions of the polysilicon layer 138, the metal layer 140, and the cap layer 142 are removed to form the control gate 136 by using the patterned photoresist as a mask. A dielectric spacer 144, such as a nitride layer, is then formed on a sidewall of the control gate 136, as shown in FIG. 8. Subsequently, the processes of forming source/drain contacts, the gate contact, and the wiring can be performed to complete the manufacture of a FINFET memory device.

The semiconductor structure of the present invention shown in FIG. 6A includes the substrate 100, the plurality of trench devices 101 arranged in array within the substrate 100, the plurality of plugs 115 on the substrate 100 corresponding to the plurality of trench devices 101, and the plurality of isolation structures 122 along a first direction (i.e. B-B direction) in the substrate 100 and adjacent to the trench device 101, the spacer 128 on each plug 115 connected with each other to define the opening 129, and the rounded fin structure 130 located within the opening 129.

Moreover, as shown in FIG. 8A, the trench device 101 is a single-sided buried strap trench capacitor. After the planarization process, the plug 115 and the spacer 128 is left with the remaining dielectric layer 112 (i.e. oxide layer) and the conformal liner 120 (i.e. nitride layer). The isolation structure 122 may include optional thermal oxide layer, nitride liner and filling oxide layer. Moreover, the gate dielectric 132 covers the fin structure 130, and the gate conductor 134 is on the gate dielectric layer 132 adjacent to the rounded fin structure 130 and isolation structure 122. The control gate 136 is formed along a second direction (A-A direction) perpendicular to the first direction located overlying the gate conductor 134 corresponding to the rounded fin structure 130. The control gate 136 sequentially includes the second gate conductor 138, the metal layer 140, and the cap layer 142 over the control gate 134. The dielectric spacer 144 is on the sidewall of the control gate 136.

Please note that though specific materials, such as oxide, nitride, polysilicon, are illustrated for specific layers in the embodiments, the person skilled in the art should appreciate that the present invention can be also achieved by selecting different materials based on the etching selectivity and the characteristic of the materials, and the materials are not limited to those described in the embodiments. That is, the present invention integrates the trench device with column-like masking technique to self-alignedly define the fin structure so as to prevent the misalignment occurred in the prior art and maintain suitable spaces for source/drain contacts to accomplish a fin type semiconductor device, such as a FINFET memory device.

The present invention has been described above with reference to preferred embodiments. However, those skilled in the art will understand that the scope of the present invention need not be limited to the disclosed preferred embodiments. On the contrary, it is intended to cover various modifications and equivalent arrangements within the scope defined in the following appended claims. The scope of the claims should be accorded the broadest interpretation so as to encompass all such modifications and equivalent arrangements.

What is claimed is:

1. A method of forming a fin structure in a substrate comprising:
providing a plurality of trench devices arranged in an array in the substrate, each of the trench devices having a plug formed on top of each of the trench devices, wherein the plug has a top surface higher than that of a surface of the substrate;
forming along a first direction in the substrate a plurality of isolation structures paralleled to each other, wherein each of the plurality of isolation structures is adjacent to the trench devices so as to define an active area between every two of the plurality of trench devices;
forming a spacer on a sidewall of each plug to define a reactive area among every four of the plurality of trench devices, wherein the reactive areas comprises a portion of the isolation structures and the substrate; and
removing the isolation structures in the reactive area such that the fin structure is formed in the substrate.

2. The method of claim 1, wherein the trench device comprises a trench capacitor.

3. The method of claim 2, wherein the trench capacitor comprises a single-sided buried strap trench capacitor.

4. The method of claim 2 further comprising a step of conformally forming a dielectric liner on the substrate prior to the isolation structure forming step.

5. The method of claim 4, wherein the isolation structure forming step comprises:
defining a plurality of paralleled openings on two opposite sides of the trench device;
partially removing the dielectric liner, the plugs, the trench devices, and the substrate to form a plurality of paralleled openings; and
filling an oxide layer in the paralleled openings such that the isolation structures are formed.

6. The method of claim 5 further comprising a step of performing a thermal oxidation on the substrate prior to the oxide layer filling step.

7. The method of claim 1, further comprising rounding the active area to form the fin structure at the time of removing the reactive area.
